(19) United States
(12) Patent Application Publication
(10) Pub. No.: US 2003/0067294 A1
(43) Pub. Date: Apr. 10, 2003

(54) Electric power meter - optical reading device

(76) Inventor: Paul Dino Holstein, Pompano Beach, FL (US)

Correspondence Address: PAUL DINO HOLSTEIN, 1141 SE 9TH TERRACE, POMPANO BEACH, FL, 33060, US

(21) Appl. No.: 09/682,700

(22) Filed: Oct. 7, 2001

(51) Int. Cl. G01R 7/00; G01R 11/32

(52) U.S. Cl. 324/142

(57) ABSTRACT

An optical translator device capable of providing information indicative of the amount of relative movement between the device and the surface of an electrical power meter's interior rotating disk. The device comprises of an optical translator device attached to the exterior of an electric power meter. The device may be attached to a host system via a wire or wirelessly. Alternatively, display or auditory devices may be built into the device to report back the speed of rotation. The device may also contain data storage to allow subsequent retrieval of rotational information for analysis at a later time. Software may be developed to use with the device that will allow a system to interpret the results of the Electric Power Meter—Optical Reading Device. This software may be useful to interpret different makes or brands of power meters or to evaluate usage over a given time period or control power consumption devices. The software can also be used to project utility costs based on different utilities rate structures.

### DETAILED DESCRIPTION

The Electric Power Meter—Optical Reading Device is a device that attaches to the exterior of an electrical power meter and reads the rotation of the interior disk through the meter's protective exterior glass. Since the speed of the rotation of the power meter indicates the power consumption, the Electric Power Meter—Optical Reading Device can be used to report the power usage at any given period of time.

What I claim as my invention is:

1. A device that attaches to the exterior of a power meter via suction cups or other method and reads the speed of the meter's internal rotating disk.
A method of reading power consumption by evaluating the speed of rotation of a power meter's internal spinning disk.
A method of translating the visible rotation of a power meter disc into a power consumption reading either through internal software built into the Electric Power Meter—Optical Reading Device or through software loaded onto a host system.
A device to read and store the relative speed of a power meter's internal disc so that the data can be evaluated either instantly or at a later time to determine power usage.
